(19) United States
(12) Patent Application Publication
(10) Pub. No.: US 2008/0205470 A1
(43) Pub. Date: Aug. 28, 2008

(54) MONOLITHIC LIGHTING DEVICE

(75) Inventors: Shyshkin Ihar, Suwon-si (KR); Kwan-Young Oh, Yongin-si (KR)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: SAMSUNG ELECTRO-MECHANICS CO., LTD., Suwon (KR)

(21) Appl. No.: 11/873,338

(22) Filed: Oct. 16, 2007

(30) Foreign Application Priority Data
Oct. 17, 2006 (KR) 1020060101001

(51) Int. Cl. H01S 5/026

(52) U.S. Cl. 372/50.23; 372/101

(57) ABSTRACT

A monolithic lighting device is disclosed. According to an embodiment of the present invention, the monolithic lighting device includes a monolithic lens, refracting a two-dimensional beam of light transferred from an outside and condensing the refracted beam into a one-dimensional beam. The monolithic lens has a first refraction surface, refracting the two-dimensional beam of light transferred from the outside to be diffused inside the monolithic lens, and a second refraction surface, converting the two-dimensional beam diffused in the first refraction surface into a one-dimensional beam by refracting the two-dimensional beam into a parallel beam to the outside if viewed from a side and condensing the refracted beam on a focal point at a distance outside if viewed from another side.

This application claims the benefit of Korean Patent Application No. 10-2006-0101001, filed on Oct. 17, 2006, in the Korean Intellectual Property Office, the disclosure of which is incorporated herein in its entirety by reference.

### BACKGROUND OF THE INVENTION

1. Field of the Invention

The present invention relates to a lighting device, more specifically to a lighting device having a monolithic lens.

2. Background Art

Today's trend toward miniaturization of photographing devices and projection systems leads to various apparatuses and methods of efficiently condensing a beam of light emitted from a light source. Particularly, as the technologies for mounting projection units or photographing devices inside compact communication apparatuses are increasingly developed, the efficiency of condensing the light has become more important than ever.

Conventionally, a plurality of lenses have been combined to refract the light projected along the X axis and Y axis in order to improve the efficiency of condensing the light. However, the attempts to increase the condensing light efficiency have not met the demand for the trend toward the miniaturization of optical devices. In other words, in the conventional art, there was a limit to how small the product can be manufactured. Also, when a beam of light passes through a plurality of lenses and air layers, there has been an increasing loss of energy.

In addition, using a plurality of lenses in a compact projection system hindered the precision during the manufacturing process.

### SUMMARY OF THE INVENTION

The present invention, accordingly, provides a lighting device generating a one-dimensional beam of light by changing the radiuses of the front and rear surfaces of a monolithic lens.

The present invention also provides a lighting device that improves the energy efficiency by using one monolithic lens in order to condense a beam of light emitted from a light source.

In addition, the present invention provides a lighting device that can be made compact and can be easily mounted in a compact apparatus by using one monolithic lens.

Other problems that the present invention solves will become more apparent through the following description.

To solve the above problems, an aspect of the present invention features a lighting device having a monolithic lens.

According to an embodiment of the present invention, the monolithic lighting device includes a monolithic lens, refracting a two-dimensional beam of light transferred from an outside and condensing the refracted beam into a one-dimensional beam; whereas the monolithic lens can include a first refraction surface, refracting the two-dimensional beam of light transferred from the outside to be diffused inside the monolithic lens; and a second refraction surface, converting the two-dimensional beam diffused in the first refraction surface into a one-dimensional beam by refracting the two-dimensional beam into a parallel beam to the outside if viewed from a side and condensing the refracted beam on a focal point at a distance outside if viewed from another side.

Of course, the monolithic lighting device includes a light source, generating and emitting a beam of light; and a collimation lens, including an incident-surface which refracts the beam of light emitted from the light source to be diffused and an exit-surface which transfers the diffused beam by refracting the diffused beam again into a parallel beam, whereas the monolithic lens can refract the two-dimensional parallel beam transferred from the exit-surface and condensing the refracted beam into a one-dimensional beam.

Also, the light source is one of a light emitting diode (LED), a laser diode (LD) and an organic light emitting diode (OLED).

According to another embodiment of the present invention, the monolithic lens can further include n reflection surfaces, n being a natural number, and the reflection surface can totally reflect the two-dimensional beam diffused inside the monolithic lens in parallel. Here, n is 1 or 2.

Also, the one-dimensional beam of light condensed from the monolithic lighting device can be transferred to a piezoelectric diffractive optical modulator which modulates an incident beam according to an operation of a piezoelectric element corresponding to a power value.

Here, the piezoelectric diffractive optical modulator can include a substrate; an insulation layer, located on the substrate; a structure layer, a center area of which is located at a distance from the insulation layer; an upper optical reflection layer, located on the center area of the structure layer and reflecting or diffracting an incident beam of light; an upper optical reflection layer passivation film, located on the upper reflection layer and passivating the upper optical reflection layer; and a piezoelectric driving element, located on the structure layer and allowing the center area of the structure layer to move up and down.

The piezoelectric diffractive optical modulator can further include a sacrificial layer, located in an upper part of the insulation layer and a lower part of the structure layer and supporting the structure layer.

### BRIEF DESCRIPTION OF THE DRAWINGS

These and other features, aspects and advantages of the present invention will become better understood with regard to the following description, appended claims and accompanying drawings where:

FIG. 1A is a side view illustrating the operation of a monolithic lighting device in accordance with an embodiment of the present invention;

FIG. 1B is a plan view illustrating the operation of a monolithic lighting device in accordance with an embodiment of the present invention;

FIG. 1C is a perspective view illustrating the refraction of a beam of light though a monolithic lighting device in accordance with an embodiment of the present invention;

FIG. 2A is a graph showing the uniformity of a beam of light in a focus corresponding to FIG. 1A;

FIG. 2B is a graph showing the thickness of a one-dimension beam of light in a focus corresponding to FIG. 1B;

FIG. 2C is a three-dimensional graph showing the uniformity and the thickness of a beam of light in a focus corresponding to FIG. 1C;

FIG. 3 illustrates a monolithic lighting device having one reflection surface in accordance with a first embodiment of the present invention;

FIG. 4 illustrates a monolithic lighting device having one reflection surface in accordance with a second embodiment of the present invention;

FIG. 5 illustrates a monolithic lighting device having two reflection surfaces in accordance with a third embodiment of the present invention;

FIG. 6 illustrates a monolithic lighting device having two reflection surfaces in accordance with a fourth embodiment of the present invention;

FIG. 7 illustrates the physical properties and the operation of a monolithic lighting device in accordance with the embodiment of FIG. 1A;

FIG. 8 is a perspective view illustrating a type of a piezoelectric optical modulator applicable to an embodiment of the present invention;

FIG. 9 is a perspective view illustrating another type of a piezoelectric optical modulator applicable to an embodiment of the present invention;

FIG. 10 is a plan view illustrating an optical modulator array consisting of the optical modulators of FIG. 8; and

FIG. 11 illustrates the principle of optical modulation in the optical modulator array of FIG. 10.

### DESCRIPTION OF THE EMBODIMENTS

There can be a variety of permutations and embodiments of the present invention. Also, certain embodiments of the present invention merely are examples for embodying the present invention and clarifying a technical spirit of the present invention. This, however, is by no means to restrict the present invention to the certain embodiments.

The terms used in the description are intended to describe certain embodiments only, and shall by no means restrict the present invention. Unless clearly used otherwise, expressions in the singular number include a plural meaning.

Hereinafter, preferred embodiments will be described in detail with reference to the accompanying drawings. Identical or corresponding elements will be given the same reference numerals, regardless of the figure number, and any redundant description of the identical or corresponding elements will not be repeated. Throughout the description of the present invention, when describing a certain technology is determined to evade the point of the present invention, the pertinent detailed description will be also omitted.

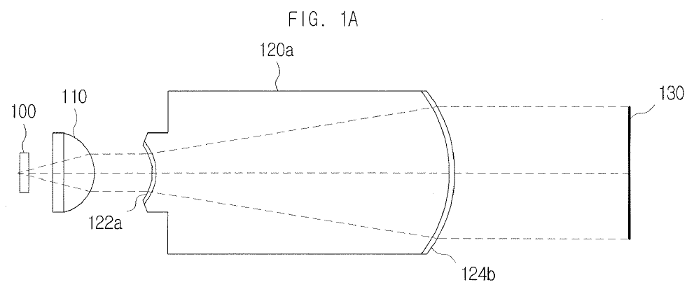

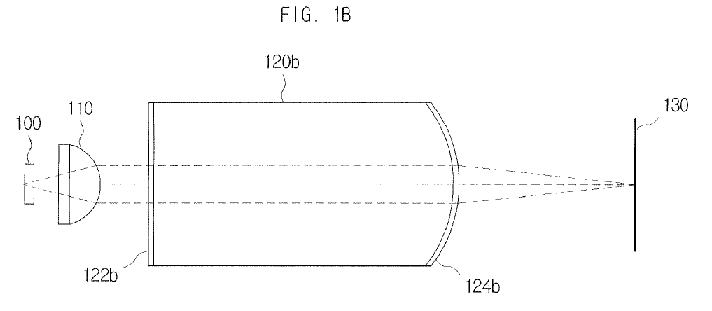

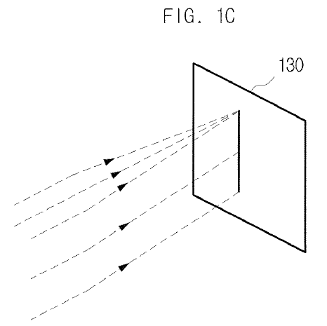

FIG. 1A is a side view illustrating the operation of a monolithic lighting device in accordance with an embodiment of the present invention. In other words, the monolithic lighting device in accordance with an embodiment of the present invention is viewed from a side (e.g. a lateral side).

FIG. 1B is a plan view illustrating the operation of a monolithic lighting device illustrated in FIG. 1A. In other words, the monolithic lighting device in accordance with an embodiment of the present invention is viewed from another side (e.g. an upper side).

Referring to FIG. 1A and FIG. 1B, the lighting device in accordance with an embodiment of the present invention includes a light source 100, a collimation lens 110 and monolithic lenses 120a and 120b (collectively referred to as 120).

The light source 100, which emits a beam of light, can be a light emitting diode (LED), a laser diode (LD) or an organic light emitting diode (OLED).

The collimation lens 110 refers to the lens diffusing the beam of light emitted from the light source 100 and then converting the diffused beam into a parallel beam of light. In particular, the collimation lens 110 includes an incident-surface, diffusing the beam of light emitted from the light source 100, and an exit-surface, penetrating the diffused beam by refracting the diffused beam into a two-dimensional parallel beam of light.

Since the collimation lens 110 performing the foregoing function is well-known to those of ordinary skill in the art to which the present invention pertains, the pertinent detailed description will be omitted.

The monolithic lens 120 can condense the parallel beam transferred from the collimation lens 110 in a certain direction by a predetermined refraction index.

If the lighting device in accordance with an embodiment of the present invention is viewed from a side (e.g. a lateral side) as illustrated in FIG. 1A, the monolithic lens 120 can refract the beam transferred through the collimation 110 by diffusing the beam into a parallel beam at a certain rate inside the monolithic lens 120 such that the parallel beam can be exited to an outside.

Referring to FIG. 1B, the monolithic lens 120 can condense the beam transferred through the collimation lens 110 on a predetermined area by diffusing the beam at a certain rate in the inside thereof and refracting the diffused beam in parallel to transfer the refracted beam to the outside.

In order to realize this, the monolithic lens 120 can include first reflective surfaces 122a and 122b, placed near the collimation lens 110, and second reflective surfaces 124a and 124b, refracting the beam passing through the monolithic lens 120 again.

Of course, as illustrated in FIG. 1B, the distance to a certain focal point can be adjusted by changing the refraction index of the foregoing first reflective surfaces 122a and 122b or the second reflective surfaces 124a and 124b.

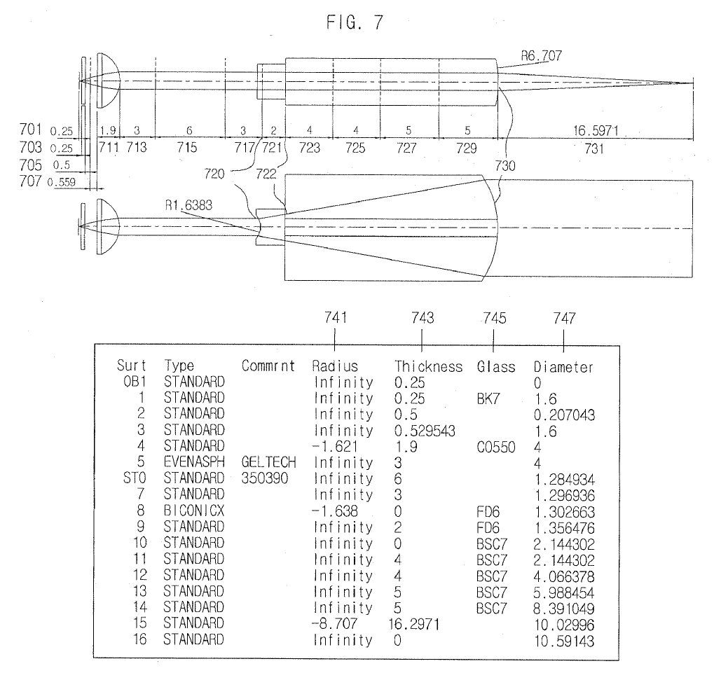

The property of the foresaid monolithic lighting device will be described in detail with reference to FIG. 7.

Here, the beam reaching the certain focal point can be projected on the image again by using a focus position 130. If an optical modulator is placed in the focus position 130, the same identification number, that is, 130 can be given to the optical modulator. The optical modulator 130 can be a piezoelectric diffractive optical modulator capable of controlling the luminance of light by using a piezoelectric member.

FIG. 1C is a perspective view illustrating the refraction of a beam of light though a monolithic lighting device in accordance with an embodiment of the present invention. More specifically, FIG. 1C illustrates the 3-dimensional condensing of the beam described with reference to FIG. 1A and FIG. 1B.

The beam of light projected from the light source 100 is diffused through the collimation lens 110 and converted into a parallel 2-dimensional beam of light before being transferred to the monolithic lens 120.

If viewed from a side (e.g. a lateral side) of the monolithic lens 120, the 2-dimensional beam of light transferred from the collimation lens 110 is diffused in the inside and then refracted in parallel to the outside. If viewed from another side (e.g. an upper or lower side) of the monolithic lens 120, the 2-dimensional beam of light can be penetrated into the inside of the monolithic lens 120 in parallel and then can be refracted so as to be condensed on a certain focal point. In other words, the 2-dimensional beam penetrating the collimation lens 110 passes through the monolithic lens 120 and is converted into a one-dimensional beam before being condensed.

The condensed beam can be modulated in various ways by the optical modulator 130.

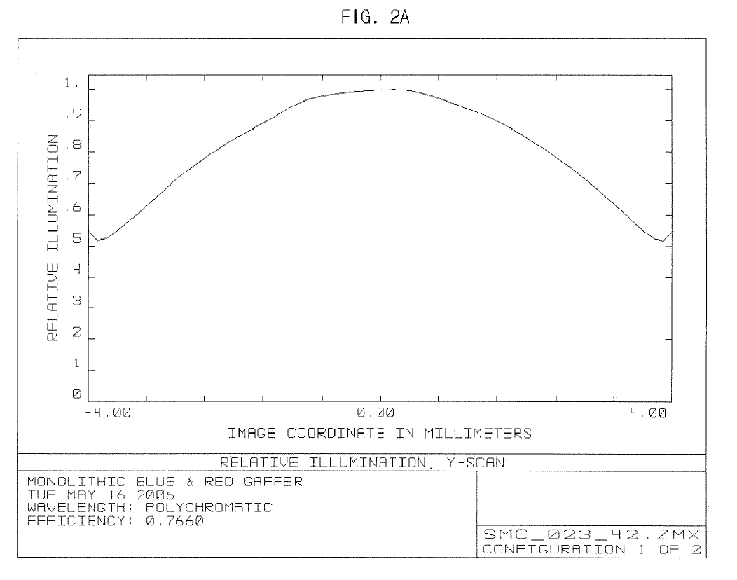

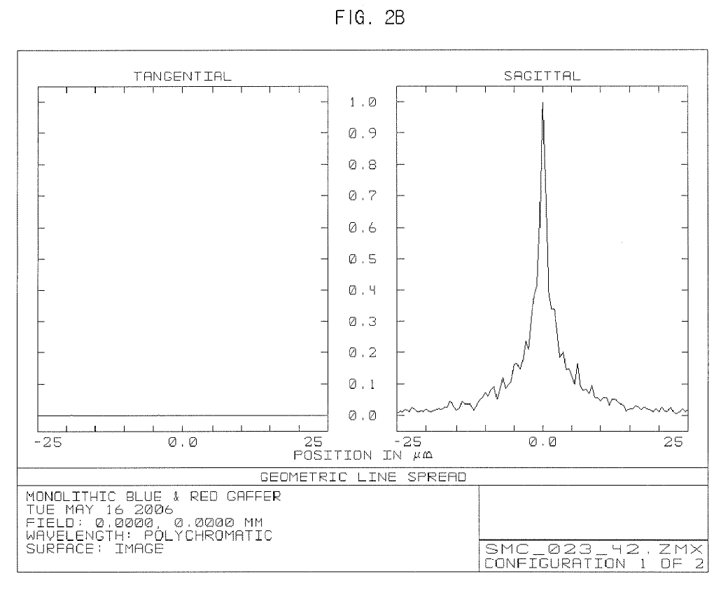

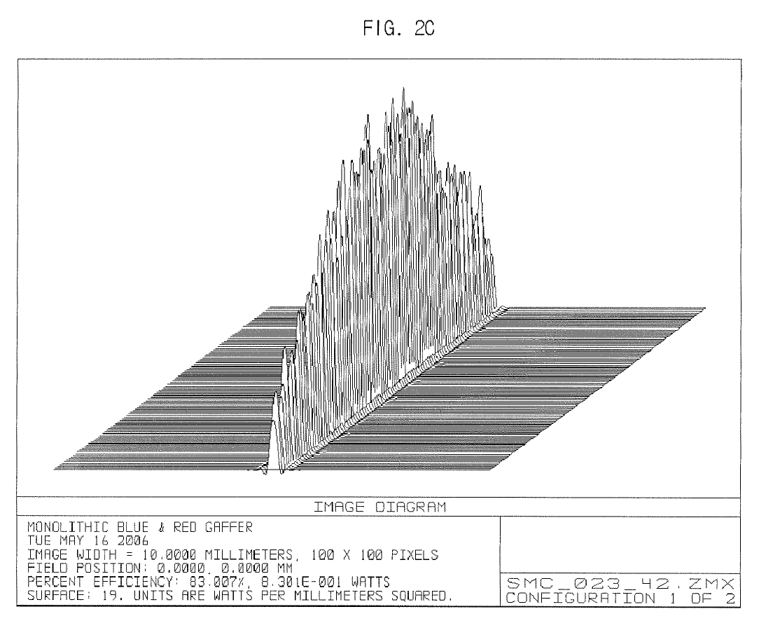

FIG. 2A is a graph showing the uniformity of a beam of light at a focus position 130 corresponding to FIG. 1A. The X axis of the graph indicates the distance spaced lengthwise from the center of the one-dimensional beam generated at the focus position 130, and the Y axis indicates the relative illumination. Referring to FIG. 2A, if the illumination value of the center is assumed as 1, an illumination value of the monolithic lighting device in accordance with the present invention is decreased away from the center.

Here, the refraction index of a refraction surface or the size of the monolithic lens of the lighting device can be changed in order to adjust the illumination value to correspond to a certain value.

Referring to FIG. 2A, it can be inferred that the beam projected from the lighting device in accordance with an embodiment of the present invention has the relative illumination value of 0.5 when the beam is located −4 mm or 4 mm away from the center.

FIG. 2B is a graph showing the thickness of a one-dimensional beam of light at a focus position 130 corresponding to FIG. 1B. The X-axis of the graph refers to a distance spaced from the center of a vertical direction to a lengthwise direction of a one-dimensional beam of light generated at the focus position 130, and the Y-axis refers to the relative illumination. The illumination value of a beam of light passing through the lighting device in accordance with an embodiment of the present invention has a large value in the center thereof and its width of 20 micrometers (based on the radiation intensity of 13.5% as compared with the maximum radiation intensity).

FIG. 2C is a three-dimensional graph showing the uniformity and the thickness of a beam of light at a focus position 130 corresponding to FIG. 1C. In other words, FIG. 2C is a 3-dimensional rendition of FIG. 2A and FIG. 2B. Since the detailed description is the same as what was described with reference to FIG. 2A and FIG. 2B, the pertinent description will be omitted.

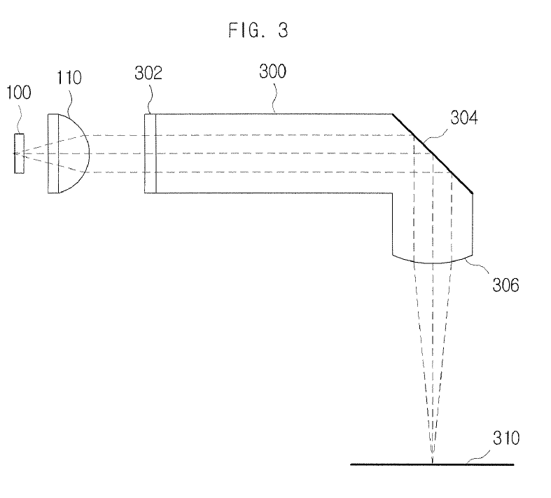

Of course, the monolithic lens in accordance with the present invention can be realized in various ways. Each of the corresponding embodiments will be described with reference to FIG. 3 through FIG. 6. Of course, it will be evident to any person of ordinary skill in the art to which the present invention pertains that other various embodiments can be realized.

The various embodiments described below can be modified according to the structures of portable devices and photographing devices, to which each lighting device is to be coupled. The description of the elements and functions identical to those of FIG. 1A through FIG. 1C will be omitted.

FIG. 3 illustrates a monolithic lighting device having one reflection surface in accordance with a first embodiment of the present invention. The monolithic lens 300 in accordance with an embodiment of the present invention can include a first refraction surface 302, a reflection surface 304 and a second refraction surface 306.

As described in FIG. 3, the reflection surface 304 of the monolithic lens 300 is located closer to the second refraction surface 306 than to the first refraction surface 302.

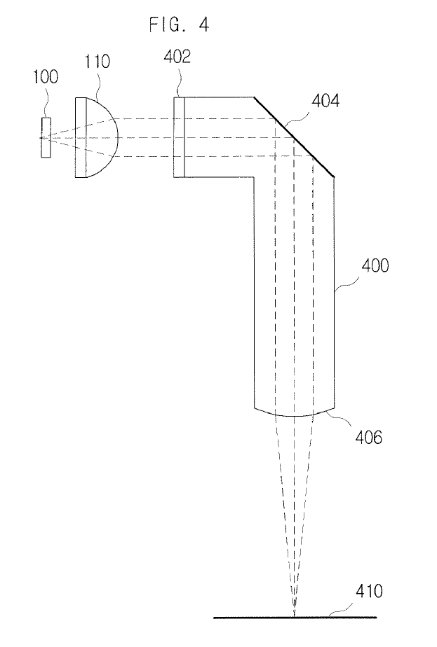

FIG. 4 illustrates a monolithic lighting device having one reflection surface in accordance with a second embodiment of the present invention. The monolithic lighting device described in FIG. 4, unlike the embodiment of FIG. 3, can be configured to allow a reflection surface 404 to be located closer to a first refraction surface 402 than to a second surface 406. As such, the position of the reflection surfaces 304 and 404 can be changed to be suitable for the volume and position of a device, which is coupled to the monolithic lighting device in accordance with an embodiment of the present invention.

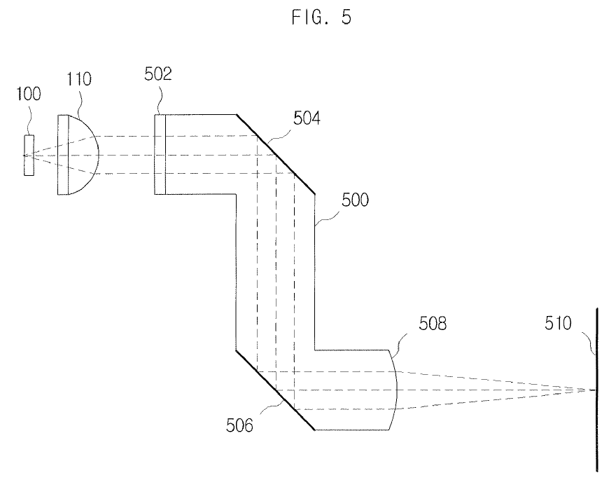

FIG. 5 illustrates a monolithic lighting device having two reflection surfaces in accordance with a third embodiment of the present invention. More specifically, the monolithic lens 500 can include a first refraction surface 502, a first reflection surface 504, a second refraction surface 506 and a second refraction surface 508.

The monolithic lens 500 illustrated in FIG. 5 can be configured to allow a beam of light reflected through the first reflection surface 504 to be reflected again through the second reflection surface 506 and then to advance in the same direction as the advancing direction of a beam of light projected from the light source 100. The direction of condensing a beam of light in a 3-dimensional space can be adjusted in various ways by controlling a 3-dimensional angle of the first reflection surface 504 and the second reflection surface 506.

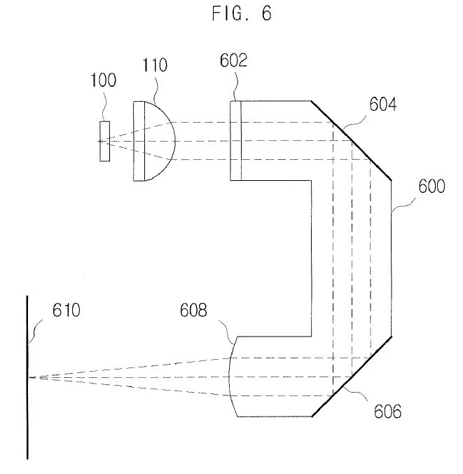

FIG. 6 illustrates a monolithic lighting device having two reflection surfaces in accordance with a fourth embodiment of the present invention. According to the embodiment of FIG. 6, the monolithic lens 600 can be configured to allow a beam of light to be reflected through a first reflection surface 604 and a second reflection surface 606 and then to advance in a different direction from the advancing direction of a beam of light projected from the light source 100, unlike the embodiment of FIG. 5.

A monolithic lens including n reflection surfaces, n being a natural number, corresponding to the volume and position of a device applied to the present invention can be suggested as an alternative embodiment in addition to various embodiments described with reference to FIG. 3 through FIG. 6.

FIG. 7 illustrates the properties and operation of a monolithic lighting device in accordance with the embodiment of FIG. 1A. The monolithic lighting device illustrated in FIG. 1A and FIG. 1B is illustrated in the upper part of FIG. 7, and a table for describing the properties and operation of the monolithic lighting device is illustrated in the lower part of FIG. 7.

A Thickness 743 of the table refers to the widths of the following areas. An area between the light source 100 of FIG. 1A and FIG. 1B and the collimation lens 110 is partitioned into 4 sections 701, 703, 705 and 707. Also, an area between the collimation lens 110 and the monolithic lens 120 is partitioned into 4 sections 711, 713, 715 and 717. As described above, since a two-dimensional beam of light is a parallel beam of light, the width of each of the areas 711, 713, 715 and 717 is changeable. An inside area of the monolithic lens 120 includes 5 sections 721, 723, 725, 727 and 729 and 3 boundary surfaces 720, 722 and 730. An area between the monolithic lens 120 and the optical modulator 130 is recognized as one section 731.

A Radius 741 of the table refers to the radiuses of each section and boundary surface.

The Radius 741 of the collimation lens 110 is −1.621. Also, the Radius 741 of the first refraction surface 720 of the monolithic lens 120 is −1.638, and the Radius 741 of the second refraction surface 730 is −8.707.

A Glass 745 of the table refers to the glass property of each element. Here, based on the boundary surface 722 of the monolithic lens 120, an area formed with the first refraction surface 720 and an area formed with the second refraction surface 730 can be made of glasses having different properties.

A Diameter 747 of the table refers to the external diameter of a beam of light diffused in each section and boundary surface while the monolithic lighting device is in operation.

Here, as described above, the refraction of the beam of light can be changed by changing the radiuses of the first refraction surface 720 and the second refraction surface 730.

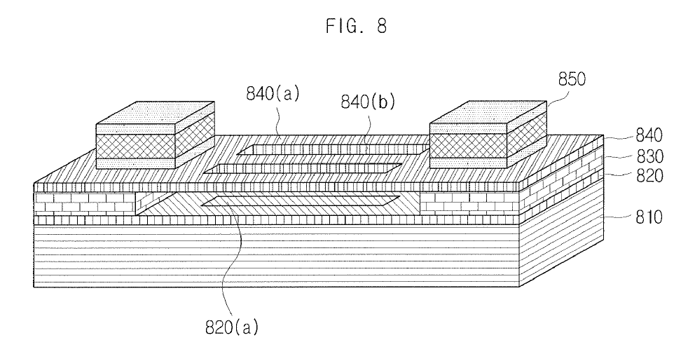

FIG. 8 through FIG. 11 illustrate a piezoelectric diffractive optical modulator, which modulates a beam of light condensed from a monolithic lighting device, in accordance with an embodiment of the present invention. Specifically, the piezoelectric diffractive optical modulator described below can be the optical modulator 130 of FIG. 1A through FIG. 1C, the optical modulator 310 of FIG. 3, the optical modulator 410 of FIG. 4, the modulator 510 of FIG. 5 and the modulator 610 of FIG. 6.

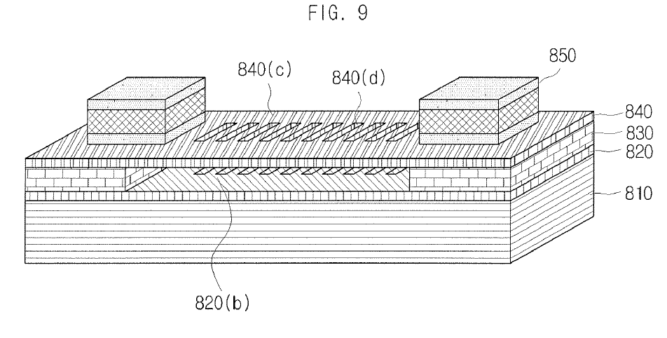

FIG. 8 is a perspective view illustrating a type of a piezoelectric optical modulator applicable to an embodiment of the present invention, and FIG. 9 is a perspective view illustrating another type of a piezoelectric optical modulator applicable to an embodiment of the present invention.

Referring to FIG. 8 and FIG. 9, the piezoelectric optical modulator applicable to an embodiment of the present invention, includes a substrate 810, an insulation layer 820, a sacrificial layer 830, a structure layer 840 and a piezoelectric driving element 850. A plurality of holes 840b and 840d are placed in a center area of the structure layer 840. Upper optical reflection layers 840a and 840c can be formed in the center area of the structure layer 840 if no holes are formed in the center area of the structure layer 840, and lower optical reflection layers 820a and 820b can be formed in the insulation layer 820 corresponding to the positions of the holes. Further, the piezoelectric driving element 850 controls the structure layer 840 to move up and down according to a level of upward and downward or leftward and rightward contraction or expansion generated by the difference in voltage between upper and lower electrodes.

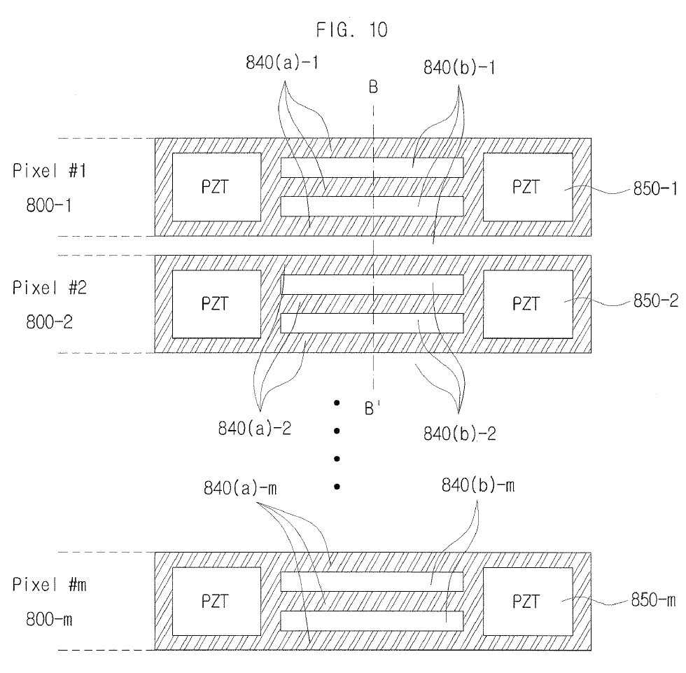

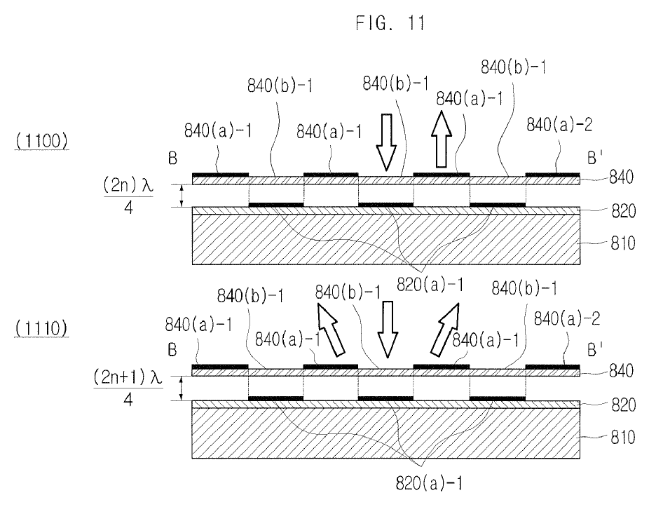

The principle of optical modulation caused by the change of height between the structure layer 840 and the insulation layer 820 will be described with reference to FIG. 10 and FIG. 11.

FIG. 10 is a plan view illustrating an optical modulator array consisting of the optical modulators of FIG. 8, and FIG. 11 illustrates the principle of optical modulation in the optical modulator array of FIG. 10. FIG. 1 is a sectional view of FIG. 10, viewed along the line BB′.

Referring to FIG. 10, the optical modulator array is configured to include m optical modulators 800-1, 800-2, . . . , and 800-m, each of which corresponds to a first pixel (pixel #1), a second pixel (pixel #2), . . . and an m^{th} pixel (pixel #m), respectively, m being a natural number. Each of upper optical reflection layers 840a-1, 840a-2, . . . and 840a-m, holes 840b-1, 840b-2, . . . and 840b-m and piezoelectric driving elements 850-1, 850-2, . . . and 850-m performs the same function as described above. The optical modulator layer deals with image information related to one-dimensional images of vertical or horizontal scanning lines (which are assumed to consist of m pixels), while each of the optical modulators 800-1, 800-2, . . . , and 800-m deals with one pixel among the m pixels constituting the vertical or horizontal scanning line.

Accordingly, the beam of light reflected and diffracted by each optical modulator is projected as a two-dimensional image to a screen by an optical scanning device. For example, in the case of a VGA resolution of 640*480, the modulation is performed 640 times for 480 vertical pixels in one surface of an optical scanning device (not shown), to thereby generate one frame of display having a resolution of 640*480. Here, the optical scanning device can use a polygon mirror, a rotating bar, or a Galvano mirror, for example.

While the following description of the principle of optical modulation is based on the first pixel (pixel #1), the same description can be obviously applied to other pixels.

In this embodiment, as described with reference to FIG. 8, it is assumed that 2 holes 840b-1 are formed in the structure layer 840. Due to the two holes 840b-1, 3 upper optical reflection layers 840a-1 are formed in an upper part of the structure layer 840. The insulation layer 820 is formed with 2 lower optical reflection layers 820a-1 corresponding to the two holes 840b-1. Also, another lower optical reflection layer 820a-1 is formed in the insulation layer 820 corresponding to a distance between a first pixel (pixel #1) and a second pixel (pixel #2). Accordingly, for each pixel, the number of the upper reflection layers 840(a)-1 is identical to that of the lower reflection layers 820a-1. This makes it possible to adjust the luminance of the modulated light using the 0^{th}-order diffracted light or ±1^{st}-order diffracted light.

Referring to 1100 of FIG. 11, in case that the wavelength of a beam of light is λ, a first power, which allows the gap between the structure layer 840 formed with the upper optical reflection layer 840a-1 and the insulation layer 820 formed with the lower optical reflection layer 820a-1 to be equal to (2n)λ/4, n being a natural number, is supplied to the piezoelectric driving element 850. At this time, in the case of a 0^{th}-order diffracted (reflected) beam of light, the overall path length difference between the light reflected by the upper optical reflection layer 840a-1 and the light reflected by the lower optical reflection layer 820a-1 is equal to nλ so that constructive interference occurs and the diffracted light renders its maximum luminance. Here, in the case of a +1^{st} or −1^{st} order diffracted light, the luminance of the light is at its minimum value due to destructive interference.

Referring to 1110 of FIG. 11, a second power, which allows the gap between the structure layer 840 formed with the upper optical reflection layer 840a-1 and the insulation layer 820 formed with the lower optical reflection layer 820a-1 to be equal to (2n+1)λ/4, n being a natural number, is supplied to the piezoelectric driving element 850. At this time, in the case of a 0th-order diffracted (reflected) beam of light, the overall path length difference between the light reflected by the upper optical reflection layer 840a-1 and the light reflected by the lower optical reflection layer 820a-1 is equal to (2n+1)λ/2 so that destructive interference occurs, and the diffracted light renders its minimum luminance. Here, in the case of the +1^{st} or −1^{st} order diffracted light, the luminance of the light is at its maximum value due to constructive interference.

As a result of such interference, the optical modulator can load signals on the beams of light by adjusting the quantity of the reflected or diffracted light. Although the foregoing describes the cases that the gap between the structure layer 840 formed with the upper optical reflection layer 840a-1 and the insulation layer 820 formed with the lower optical reflection layer 820a-1 is (2n)λ/4 or (2n+1)λ/4, it is obvious that a variety of embodiments, which are able to operate with a gap adjusting the intensity of interference by diffraction and reflection of the incident light, can be applied to the present invention.

Although some embodiments of the present invention have been described, anyone of ordinary skill in the art to which the invention pertains should be able to understand that a very large number of permutations are possible without departing the spirit and scope of the present invention and its equivalents, which shall only be defined by the claims appended below.

What is claimed is:

1. A monolithic lighting device comprising:
a monolithic lens, refracting a two-dimensional beam of light transferred from an outside and condensing the refracted beam into a one-dimensional beam;
whereas the monolithic lens comprises:
a first refraction surface, refracting the two-dimensional beam of light transferred from the outside to be diffused inside the monolithic lens; and
a second refraction surface, converting the two-dimensional beam diffused in the first refraction surface into a one-dimensional beam by refracting the two-dimensional beam into a parallel beam to the outside if viewed from a side and condensing the refracted beam on a focal point at a distance outside if viewed from another side.

2. The device of claim 1, further comprising:
a light source, generating and emitting a beam of light; and
a collimation lens, including an incident-surface which refracts the beam of light emitted from the light source to be diffused and an exit-surface which transfers the diffused beam by refracting the diffused beam again into a parallel beam,
whereas the monolithic lens refracts the two-dimensional parallel beam transferred from the exit-surface and condensing the refracted beam into a one-dimensional beam.

3. The device of claim 2, wherein the light source is one of a light emitting diode (LED), a laser diode (LD) and an organic light emitting diode (OLED).

4. The device of claim 1, wherein the monolithic lens further comprises n reflection surfaces, n being a natural number, and
the reflection surface totally reflects the two-dimensional beam diffused inside the monolithic lens in parallel.

5. The device of claim 4, wherein n is 1 or 2.

6. The device of claim 1, wherein the one-dimensional beam of light condensed from the monolithic lighting device is transferred to a piezoelectric diffractive optical modulator which modulates an incident beam according to an operation of a piezoelectric element corresponding to a power value.

7. The device of claim 6, wherein the piezoelectric diffractive optical modulator comprises:
a substrate;
an insulation layer, located on the substrate;
a structure layer, a center area of which is located at a distance from the insulation layer;
an upper optical reflection layer, located on the center area of the structure layer and reflecting or diffracting an incident beam of light;
an upper optical reflection layer passivation film, located on the upper reflection layer and passivating the upper optical reflection layer; and
a piezoelectric driving element, located on the structure layer and allowing the center area of the structure layer to move up and down.

8. The device of claim 7, wherein the piezoelectric diffractive optical modulator further comprises a sacrificial layer, located in an upper part of the insulation layer and a lower part of the structure layer and supporting the structure layer.
